(19) United States
(12) Patent Application Publication
(10) Pub. No.: US 2024/0324284 A1
(43) Pub. Date: Sep. 26, 2024

(54) DISPLAY APPARATUS AND METHOD OF MANUFACTURING THE SAME

(71) Applicant: Samsung Display Co., Ltd., Yongin-Si (KR)

(72) Inventors: Ran Kim, Yongin-si (KR); Sunwoo Lee, Yongin-si (KR)

(21) Appl. No.: 18/409,010

(22) Filed: Jan. 10, 2024

(30) Foreign Application Priority Data
Mar. 24, 2023 (KR) 10-2023-0039230
Aug. 7, 2023 (KR) 10-2023-0103150

(51) Int. Cl. H10K 59/121; H10K 59/12

(52) U.S. Cl. CPC H10K 59/1213; H10K 59/1201

(57) ABSTRACT

A display apparatus includes a substrate, a buffer layer located on the substrate, a first thin-film transistor located on the buffer layer, the first thin-film transistor including a first semiconductor layer and a first gate electrode insulated from the first semiconductor layer. The first semiconductor layer includes an oxide semiconductor. A first inorganic insulating layer is located between the first semiconductor layer and the first gate electrode, and emits at least 1×10¹⁹ mole/cm³ of hydrogen (H₂).

### CROSS-REFERENCE TO RELATED APPLICATION(S)

This application is based on and claims priority, under 35 U.S.C. § 119, to Korean Patent Application Nos. 10-2023-0039230 and 10-2023-0103150, respectively filed on Mar. 24, 2023 and Aug. 7, 2023 in the Korean Intellectual Property Office, the disclosures of which are incorporated by reference herein in their entirety.

### BACKGROUND

### 1. Field

One or more embodiments relate to a display apparatus and a method of manufacturing the same.

### 2. Description of the Related Art

Today, display apparatuses are used for various purposes. Due to the wide application of display apparatuses, their thicknesses and weights have decreased.

Organic light-emitting display apparatuses, among different types of display apparatuses, have attracted attention as promising next-generation display apparatuses due to their wide viewing angles, high contrast, and fast response times.

In general, in an organic light-emitting display apparatus, a thin-film transistor and an organic light-emitting diode as a display element are formed on a substrate, and the organic light-emitting diode emits light. Such an organic light-emitting display apparatus is used as a display for a small product such as a mobile phone, or for a large product such as a television.

### SUMMARY

One or more embodiments include a display apparatus with improved reliability and visibility and a method of manufacturing the display apparatus. However, the embodiments are examples, and do not limit the scope of the disclosure.

Additional aspects will be set forth in the description which follows and, in part, will be apparent from the description, or may be learned by practice of the presented embodiments.

According to an aspect of the disclosure, a display apparatus includes a substrate, a buffer layer located on the substrate, a first thin-film transistor located on the buffer layer, and including a first semiconductor layer and a first gate electrode insulated from the first semiconductor layer, the first semiconductor layer including an oxide semiconductor, and a first inorganic insulating layer located between the first semiconductor layer and the first gate electrode, wherein a hydrogen (H₂) emission amount of the first inorganic insulating layer is at least 1×10¹⁹ mole/cm³.

A nitrogen oxide (NOx) emission amount of the first inorganic insulating layer may be no higher than 1×10¹⁹ mole/cm³.

A thickness of the first inorganic insulating layer may range from about 1000 Å to about 2000 Å.

The first inorganic insulating layer may include silicon oxide (SiOx).

A hydrogen (H₂) emission amount of the buffer layer may be at least 3×10¹⁹ mole/cm³.

A hydrogen (H₂) concentration of the buffer layer may be no higher than 8×10²⁰ atom/cm³.

The buffer layer may include one of silicon oxide (SiOx) and silicon nitride (SiNx).

A thickness of the first semiconductor layer may range from about 20 Å to about 400 Å.

The first semiconductor layer may include at least one of indium gallium zinc oxide (IGZO), indium tin gallium oxide (ITGO), indium tin gallium zinc oxide (ITGZO), indium tin oxide (ITO), indium gallium oxide (IGO), and indium zinc oxide (IZO).

According to another aspect of the disclosure, a method of manufacturing a display apparatus includes forming a buffer layer on a substrate, forming, on the buffer layer, a first semiconductor layer including an oxide semiconductor, forming a first inorganic insulating layer on the first semiconductor layer, and forming a first gate electrode on the first inorganic insulating layer to form a first thin-film transistor including the first semiconductor layer and the first gate electrode insulated from the first semiconductor layer, wherein a hydrogen (H₂) emission amount of the first inorganic insulating layer is at least 1×10¹⁹ mole/cm³.

The forming of the buffer layer on the substrate may include forming the buffer layer on the substrate through hydrogen (H₂) plasma treatment.

The forming of the first semiconductor layer including the oxide semiconductor may involve a sputtering process, wherein power in the sputtering process ranges from about 4 KW to about 11 kW.

The forming of the first semiconductor layer including the oxide semiconductor may involve a sputtering process, wherein pressure in the sputtering process ranges from about 0.3 Pa to about 0.5 Pa.

The forming of the first semiconductor layer including the oxide semiconductor may involve a sputtering process, wherein partial pressure of oxygen (O₂) in the sputtering process ranges from about 20% to about 40%.

The forming of the first semiconductor layer including the oxide semiconductor may involve a sputtering process, wherein defects of a lower buffer layer due to plasma damage in the sputtering process are no higher than 8×10¹⁴ spins/cm².

In the forming of the first inorganic insulating layer on the first semiconductor layer, a temperature of a process may range from about 300 to about 400° C.

A nitrogen oxide (NOx) emission amount of the first inorganic insulating layer may be no higher than 1×10¹⁹ mole/cm³.

A hydrogen (H₂) emission amount of the first inorganic insulating layer may be at least 1×10¹⁹ mole/cm³.

A thickness of the first inorganic insulating layer may range from about 1000 Å to about 2000 Å.

A thickness of the first semiconductor layer may range from about 20 Å to about 400 Å.

### BRIEF DESCRIPTION OF THE DRAWINGS

The above and other aspects, features, and advantages of certain embodiments will be more apparent from the following description taken in conjunction with the accompanying drawings, in which:

FIG. 1 is a perspective view schematically illustrating a display apparatus, according to an embodiment;

FIG. 2 is a cross-sectional view schematically illustrating each pixel of a display apparatus, according to an embodiment;

FIG. 3 is a view schematically illustrating each optical unit of a color conversion-transmissive layer of FIG. 2;

FIG. 4 is an equivalent circuit diagram illustrating a light-emitting diode included in a display apparatus and a pixel circuit electrically connected to the light-emitting diode, according to an embodiment;

FIGS. 5A and 5B are cross-sectional views schematically illustrating a display apparatus, according to an embodiment; and

FIGS. 6, 7, 8, 9, 10, 11, 12, 13, 14, and 15 are cross-sectional views schematically illustrating a method of manufacturing a display apparatus.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are described below by referring to the figures, to explain aspects of the present description.

As the disclosure allows for various changes and numerous embodiments, certain embodiments will be illustrated in the drawings and described in the detailed description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings, wherein the same or corresponding elements are denoted by the same reference numerals throughout and a repeated description thereof is omitted.

Although the terms “first,” “second,” etc. may be used to describe various elements, these elements should not be limited by these terms. These terms are only used to distinguish one element from another.

As used herein, the singular forms “a,” “an,” and “the” are intended to include the plural forms as well, unless the context clearly indicates otherwise.

It will be understood that the terms “including,” and “having,” are intended to indicate the existence of the features or elements described in the specification, and are not intended to preclude the possibility that one or more other features or elements may exist or may be added.

It will be further understood that, when a layer, region, or component is referred to as being “on” another layer, region, or component, it may be directly on the other layer, region, or component, or may be indirectly on the other layer, region, or component with intervening layers, regions, or components therebetween.

Sizes of components in the drawings may be exaggerated or reduced for convenience of explanation. For example, because sizes and thicknesses of elements in the drawings are arbitrarily illustrated for convenience of explanation, the disclosure is not limited thereto.

When a certain embodiment may be implemented differently, a specific process order may be different from the described order. For example, two consecutively described processes may be performed substantially at the same time or may be performed in an order that is reverse of the order of description.

“A and/or B” is used herein to select only A, select only B, or select both A and B. “At least one of A and B” is used to select only A, select only B, or select both A and B.

It will be understood that when a layer, a region, or a component is referred to as being “connected” to another layer, region, or component, it may be “directly connected” to the other layer, region, or component and/or may be “indirectly connected” to the other layer, region, or component with other layers, regions, or components interposed therebetween. For example, when a layer, a region, or a component is referred to as being “electrically connected,” it may be directly electrically connected, and/or may be indirectly electrically connected with intervening layers, regions, or components therebetween.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

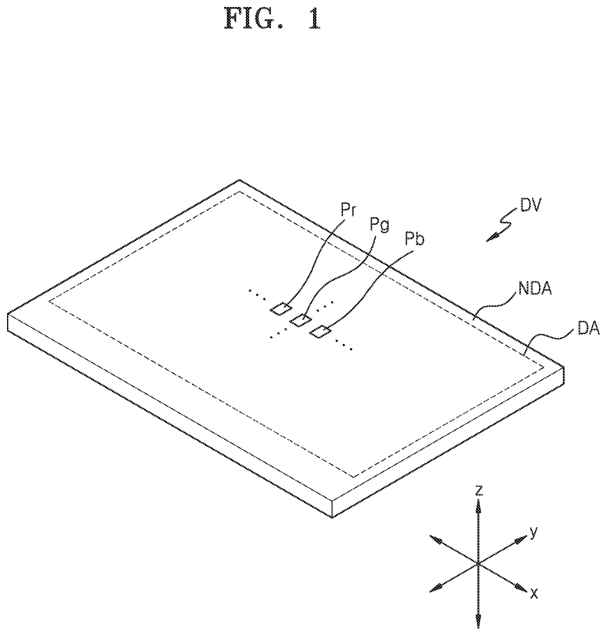

FIG. 1 is a perspective view schematically illustrating a display apparatus, according to an embodiment.

Referring to FIG. 1, a display apparatus DV may include a display area DA and a non-display area NDA outside the display area DA. The display apparatus may provide an image through an array of pixels that are two-dimensionally arranged in an x-y plane in the display area DA. The plurality of pixels may include a first pixel, a second pixel, and a third pixel, and for convenience of explanation, the following will be described assuming that the first pixel is a red pixel Pr, the second pixel is a green pixel Pg, and the third pixel is a blue pixel Pb.

The red pixel Pr, the green pixel Pg, and the blue pixel Pb are areas where red light, green light, and blue light may be respectively emitted, and the display apparatus DV may provide an image by using light emitted from the pixels.

The non-display area NDA where an image is not provided may entirely surround the display area DA. A driver or a main voltage line for providing an electrical signal or power to pixel circuits may be located in the non-display area NDA. A pad to which an electronic device or a printed circuit board may be electrically connected may be included in the non-display area NDA.

The display area DA may have any of polygonal shapes including a quadrangular shape as shown in FIG. 1. For example, the display area DA may have a rectangular shape in which a horizontal length is greater than a vertical length, a rectangular shape in which a horizontal length is less than a vertical length, or a square shape. Alternatively, the display area DA may have any of various shapes such as an elliptical shape or a circular shape.

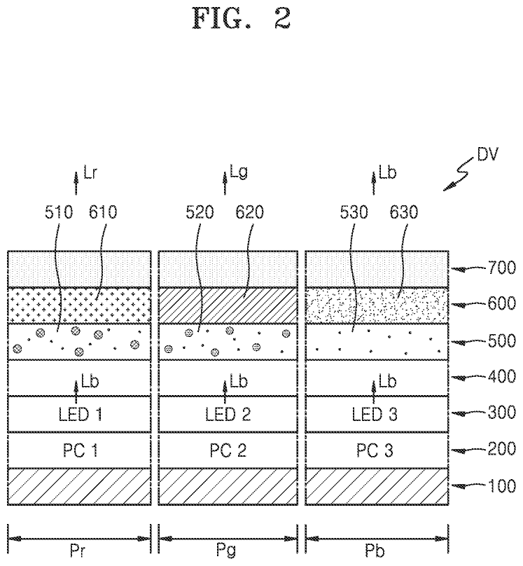

FIG. 2 is a cross-sectional view schematically illustrating each pixel of a display apparatus, according to an embodiment.

Referring to FIG. 2, the display apparatus DV may include a circuit layer 200 on a substrate 100. The circuit layer 200 may include first to third pixel circuits PC1, PC2, and PC3, and the first to third pixel circuits PC1, PC2, and PC3 may be respectively electrically connected to first to third light-emitting diodes LED1, LED2, and LED3 of a light-emitting diode layer 300.

Each of the first to third light-emitting diodes LED1, LED2, and LED3 may include an organic light-emitting diode including an organic material. Alternatively, each of the first to third light-emitting diodes LED1, LED2, and LED3 may be an inorganic light-emitting diode including an inorganic material. The inorganic light-emitting diode may include a PN junction diode including inorganic semiconductor-based materials. When a voltage is applied to a PN junction diode in a forward direction, holes and electrons may be injected, and energy generated by recombination of the holes and electrons may be converted into light energy to emit light of a certain color. The inorganic light-emitting diode may have a width of several to hundreds of micrometers or several to hundreds of nanometers. Alternatively, the light-emitting diode LED may be a light-emitting diode including quantum dots. As described above, an emission layer of the light-emitting diode LED may include an organic material, an inorganic material, quantum dots, an organic material and quantum dots, or an inorganic material and quantum dots.

The first to third light-emitting diodes LED1, LED2, and LED3 may emit light of the same color. For example, light (e.g., blue light Lb) emitted from the first to third light-emitting diodes LED1, LED2, and LED3 may pass through an encapsulation layer 400 on the light-emitting diode layer 300 and may pass through a color conversion-transmissive layer 500.

The color conversion-transmissive layer 500 may include optical units through which light (e.g., the blue light Lb) emitted from the light-emitting diode layer 300 is transmitted after color conversion or without color conversion. For example, the color conversion-transmissive layer 500 may include color conversion units for converting light (e.g., the blue light Lb) emitted from the light-emitting diode layer 300 into light of another color, and a transmissive unit 530 for transmitting light (e.g., the blue light Lb) emitted from the light-emitting diode layer 300 without color conversion. The color conversion-transmissive layer 500 may include a first color conversion unit 510 corresponding to the red pixel Pr, a second color conversion unit 520 corresponding to the green pixel Pg, and the transmissive unit 530 corresponding to the blue pixel Pb. The first color conversion unit 510 may convert the blue light Lb into red light Lr, and the second color conversion layer 520 may convert the blue light Lb into green light Lg. The transmissive unit 530 may transmit the blue light Lb without conversion.

A color layer 600 may be located on the color conversion-transmissive layer 500. The color layer 600 may include first to third color filters 610, 620, and 630 of different colors. For example, the first color filter 610 may be a red color filter, the second color filter 620 may be a green color filter, and the third color filter 630 may be a blue color filter.

Light color-converted and light transmitted through the color conversion-transmissive layer 500 may have improved color purity while passing through the first to third color filters 610, 620, and 630. Also, the color layer 600 may prevent or minimize external light (e.g., light incident on the display apparatus DV from the outside of the display apparatus DV) from being reflected and viewed by a user.

A light-transmitting base layer 700 may be provided on the color layer 600. The light-transmitting base layer 700 may include glass or a light-transmitting organic material. For example, the light-transmitting base layer 700 may include a light-transmitting organic material such as an acrylic resin.

In an embodiment, the light-transmitting base layer 700 is a substrate, and the color layer 600 and the color conversion-transmissive layer 500 may be formed on the light-transmitting base layer 700 and then the color conversion-transmissive layer 500 may be integrated to face the encapsulation layer 400.

Alternatively, the color conversion-transmissive layer 500 and the color layer 600 may be sequentially formed on the encapsulation layer 400, and the light-transmitting base layer 700 may be formed by being directly applied to and cured on the color layer 600. Although not shown, other optical films, for example, an anti-reflection (AR) film, may be located on the light-transmitting base layer 700.

Examples of the display apparatus DV having the above structure may include a television, a billboard, a screen for a movie theater, a tablet PC, and a laptop computer.

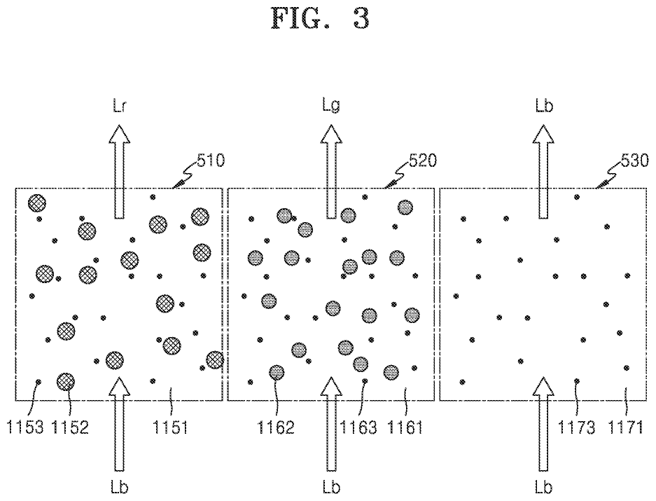

FIG. 3 is a view schematically illustrating each optical unit of the color conversion-transmissive layer of FIG. 2.

Referring to FIG. 3, the first color conversion layer 510 may convert incident blue light Lb into red light Lr. As shown in FIG. 3, the first color conversion unit 510 may include a first photosensitive polymer 1151, first quantum dots 1152 and first scattering particles 1153 dispersed in the first photosensitive polymer 1151.

The first quantum dots 1152 may be excited by the blue light Lb to isotropically emit the red light Lr having a longer wavelength than the blue light Lb. The first photosensitive polymer 1151 may be an organic material having light transmission. The first scattering particles 1153 may scatter the blue light Lb not absorbed by the first quantum dots 1152 so that more first quantum dots 1152 are excited, thereby improving color conversion efficiency. The first scattering particles 1153 may be, for example, titanium oxide (TiO₂) or metal particles. The first quantum dots 1152 may be selected from among a group II-VI compound, a group III-V compound, a group IV-VI compound, a group IV element, a group IV compound, and a combination thereof.

The second color conversion unit 520 may convert blue light Lb into green light Lg. As shown in FIG. 3, the second color conversion unit 520 may include a second photosensitive polymer 1161, and second quantum dots 1162 and second scattering particles 1163 dispersed in the second photosensitive polymer 1161.

The second quantum dots 1162 may be excited by the blue light Lb to isotropically emit the green light Lg having a longer wavelength than the blue light Lb. The second photosensitive polymer 1161 may be an organic material having light transmission.

The second scattering particles 1163 may scatter the blue light not absorbed by the second quantum dots 1162 so that more second quantum dots 1162 are excited, thereby improving color conversion efficiency. The second scattering particles 1163 may be, for example, titanium oxide (TiO₂) or metal particles. The second quantum dots 1162 may be selected from among a group II-VI compound, a group III-V compound, a group IV-VI compound, a group IV element, a group IV compound, and a combination thereof.

In an embodiment, the first quantum dots 1152 and the second quantum dots 1162 may be the same material. In this case, sizes of the first quantum dots 1152 may be greater than sizes of the second quantum dots 1162.

The transmissive unit 530 may transmit blue light Lb without converting the blue light Lb incident on the transmissive unit 530. As shown in FIG. 3, the transmissive unit 530 may include a third photosensitive polymer 1171 in which third scattering particles 1173 are dispersed. The third photosensitive polymer 1171 may be an organic material having light transmission such as a silicon resin or an epoxy resin, and may be the same material as the first and second photosensitive polymers 1151 and 1161. The third scattering particles 1173 may scatter and emit the blue light Lb, and may be the same material as the first and second scattering particles 1153.

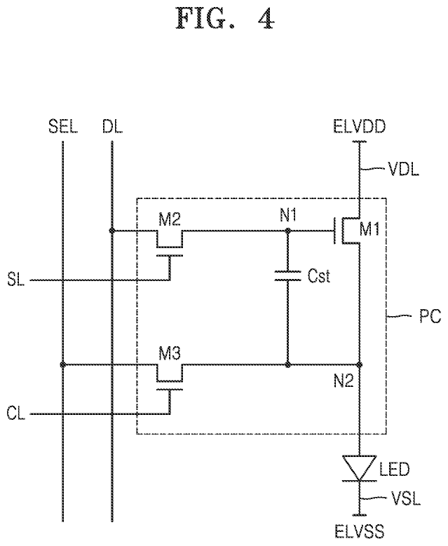

FIG. 4 is an equivalent circuit diagram illustrating a light-emitting diode included in a display apparatus and a pixel circuit electrically connected to the light-emitting diode, according to an embodiment.

Referring to FIG. 4, for example, a first electrode (e.g., an anode) of a light-emitting diode LED, may be connected to a pixel circuit PC, and a second electrode (e.g., a cathode) of the light-emitting diode LED may be connected to a common voltage line VSL that provides a common power supply voltage ELVSS. The light-emitting diode LED may emit light at a luminance corresponding to the amount of current supplied from the pixel circuit PC.

The light-emitting diode LED of FIG. 4 may correspond to the first to third light-emitting diodes LED1, LED2, and LED3 of FIG. 2, and the pixel circuit PC of FIG. 4 may correspond to the first to third pixel circuits PC1, PC2, and PC3 of FIG. 2.

The pixel circuit PC may control the amount of current flowing from a driving power supply voltage ELVDD to the common power supply voltage ELVSS via the light-emitting diode LED in response to a data signal. The pixel circuit PC may include a driving transistor M1, a switching transistor M2, a sensing transistor M3, and a storage capacitor Cst.

Each of the driving transistor M1, the switching transistor M2, and the sensing transistor M3 may be an oxide semiconductor thin-film transistor including a semiconductor layer formed of an oxide semiconductor, or may be a silicon semiconductor thin-film transistor including a semiconductor layer formed of polysilicon. Each of the driving transistor M1, the switching transistor M2, and the sensing transistor M3 may include a source electrode (or a source region) and a drain electrode (or a drain region).

The source electrode (or the source region) of the driving transistor M1 may be connected to a driving voltage line VDL that supplies the driving power supply voltage ELVDD, and the drain electrode (or the drain region) of the driving transistor M1 may be connected to the first electrode (e.g., the anode) of the light-emitting diode LED. A gate electrode of the driving transistor M1 may be connected to a first node N1. The driving transistor M1 may control the amount of current flowing from the driving power supply voltage ELVDD to the light-emitting diode LED in response to a voltage of the first node N1. However, positions of the source electrode (or the source region) and the drain electrode (or the drain region) may be changed.

The switching transistor M2 may be a switching transistor. The source electrode (or the source region) of the switching transistor M2 may be connected to a data line DL, and the drain electrode (or the drain region) of the switching transistor M2 may be connected to the first node N1. A gate electrode of the switching transistor M2 may be connected to a scan line SL. The switching transistor M2 may be turned on when a scan signal is applied to the scan line SL, to electrically connect the data line DL to the first node N1. However, positions of the source electrode (or the source region) and the drain electrode (or the drain region) may be changed.

The sensing transistor M3 may be an initialization transistor and/or a sensing transistor. The drain electrode (or the drain region) of the sensing transistor M3 may be connected to a second node N2, and the source electrode (or the source region) of the sensing transistor M3 may be connected to a sensing line SEL. A gate electrode of the sensing transistor M3 may be connected to a control line CL. However, positions of the source electrode (or the source region) and the drain electrode (or the drain region) may be changed.

The storage capacitor Cst may be connected between the first node N1 and the second node N2. For example, a first capacitor electrode of the storage capacitor Cst may be connected to the gate electrode of the driving transistor M1, and a second capacitor electrode of the storage capacitor Cst may be connected to the first electrode (e.g., the anode) of the light-emitting diode LED.

Although three transistors are illustrated in FIG. 4, the disclosure is not limited thereto. The pixel circuit PC may include four or more transistors.

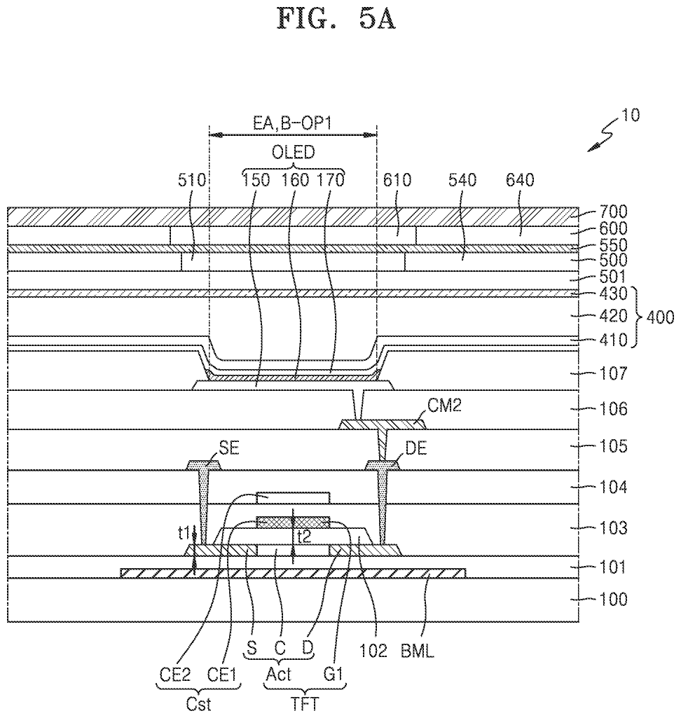

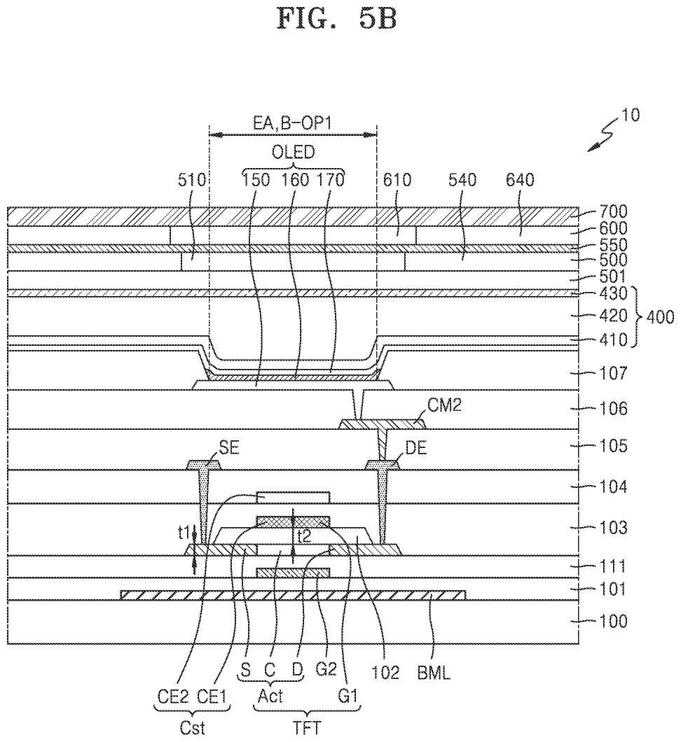

FIGS. 5A and 5B are cross-sectional views schematically illustrating a display apparatus, according to an embodiment.

Referring to FIG. 5A, a lower metal layer BML may be formed on the substrate 100, and a buffer layer 101 may be formed on the lower metal layer BML. Although not shown, the substrate 100 may include a first base layer, a first barrier layer, a second base layer, and a second barrier layer. In an embodiment, the first base layer, the first barrier layer, the second base layer, and the second barrier layer may be sequentially stacked in a thickness direction of the substrate 100.

At least one of the first base layer and the second base layer may include a polymer resin such as polyethersulfone, polyarylate, polyetherimide, polyethylene naphthalate, polyethylene terephthalate, polyphenylene sulfide, polyimide, polycarbonate, cellulose triacetate, or cellulose acetate propionate.

Each of the first barrier layer and the second barrier layer is a barrier layer for preventing penetration of an external foreign material and may have a single or multi-layer structure including an inorganic material such as silicon nitride (SiNx), silicon oxide (SiO₂), and/or silicon oxynitride (SiON).

The lower metal layer BML may be located on the substrate 100. The lower metal layer BML may overlap a first thin-film transistor TFT. The lower metal layer BML may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu). The lower metal layer BML may have a single or multi-layer structure including the above material.

In the related art, at an edge portion compared to a central portion of a substrate of a display apparatus, a degree of damage to an interface between the buffer layer 101 and a first semiconductor layer Act during a process of depositing a semiconductor layer on the buffer layer 101 may be high. At the edge portion of the substrate of the display apparatus, because the degree of damage to the interface between the buffer layer 101 and the first semiconductor layer Act is increased compared to the central portion of the substrate 100, a portion including the damaged interface at the edge portion of the substrate 100 may act as an electron trap site. Due to a decrease in hydrogen (H₂) outgassing and an increase in nitrogen oxide (NOx) outgassing at the edge portion compared to the central portion of the substrate 100 of the display apparatus, constant current stress characteristics may be degraded at the edge portion compared to the central portion of the substrate 100, thereby reducing the reliability or luminance of the display apparatus.

In order to improve the constant current stress characteristics at the edge portion of the substrate 100 of the display apparatus DV, the film quality of a display panel 10 may be changed. In detail, the constant current stress characteristics of the substrate 100 of the display apparatus DV may be improved by improving the film quality of the buffer layer 101, the first semiconductor layer Act, or a first inorganic insulating layer 102 located on the first semiconductor layer Act, which will be described in detail.

The buffer layer 101 may be located on the lower metal layer BML. The buffer layer 101 may include an inorganic insulating material such as silicon nitride (SiNX), silicon oxynitride (SiON), or silicon oxide (SiO₂), and may have a single or multi-layer structure including the inorganic insulating material.

In an embodiment, a hydrogen (H₂) emission amount of the buffer layer 101 may be 3×10¹⁹ mole/cm³ or more. A hydrogen (H₂) concentration in the film of the buffer layer 101 may be 8×10²⁰ atom/cm³ or less. The constant current stress characteristics at the edge portion of the substrate 100 may be improved by increasing a hydrogen (H₂) emission amount of the buffer layer 101. When a hydrogen (H₂) emission amount of the buffer layer 101 is less than 3×10¹⁹ mole/cm³ or a hydrogen (H₂) concentration is greater than 8×10²⁰ atom/cm³, the constant current stress characteristics may be degraded at the edge portion of the display apparatus, thereby adversely affecting the reliability or luminance of the display apparatus. After the buffer layer 101 is formed, dangling bonds may be reduced through hydrogen (H₂) plasma treatment, which will be described below in more detail.

In an embodiment, the first semiconductor layer Act may be located on the buffer layer 101. The first semiconductor layer Act may include an oxide semiconductor. The first semiconductor layer Act may include at least one of indium gallium zinc oxide (IGZO), indium tin gallium oxide (ITGO), indium tin gallium zinc oxide (ITGZO), indium tin oxide (ITO), indium gallium oxide (IGO), and indium zinc oxide (IZO).

A thickness t1 of the first semiconductor layer Act may range from 20 Å to 400 Å. When the thickness t1 of the first semiconductor layer Act is less than 20 Å or greater than 400 Å, the characteristics and reliability of the first thin-film transistor TFT including the first semiconductor layer Act may be degraded. In detail, when the thickness t1 of the first semiconductor layer Act ranges from 20 Å to 400 Å, the first thin-film transistor TFT may have a desired threshold voltage or electron mobility.

The first semiconductor layer Act may be deposited on the buffer layer 101 through plasma-enhanced chemical vapor deposition (PECVD). The plasma-enhanced chemical vapor deposition (PECVD) used to form the first semiconductor layer Act will be described below in more detail.

The first semiconductor layer Act may include a channel region C and a drain region D and a source region located on both sides of the channel region C. A first gate electrode G1 may be located on the first semiconductor layer Act. The first semiconductor layer Act and the first gate electrode G1 may constitute the first thin-film transistor TFT.

The first gate electrode G1 may overlap the channel region C of the first semiconductor layer Act. The first gate electrode G1 may include a low-resistance metal material. The first gate electrode G1 may include a conductive material including molybdenum (Mo), aluminum (Al), copper (Cu), or titanium (Ti), and may have a single or multi-layer structure including the above material.

The first inorganic insulating layer 102 may be located between the first semiconductor layer Act and the first gate electrode G1. The first inorganic insulating layer 102 may include an inorganic insulating material such as silicon oxide (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), or zinc oxide (ZnO).

A hydrogen (H₂) emission amount of the first inorganic insulating layer 102 may be 1×10¹⁹ mole/cm³ or more. Alternatively, a nitrogen oxide (NOx) emission amount of the first inorganic insulating layer 102 may be no higher than 1×10¹⁹ mole/cm³. The constant current stress characteristics at the edge portion of the display apparatus DV may be improved by increasing a hydrogen (H₂) emission amount and reducing a nitrogen oxide (NOx) emission amount of the first inorganic insulating layer 102. When a hydrogen (H₂) emission amount of the first inorganic insulating layer 102 is less than 1×10¹⁹ mole/cm³ or a nitrogen oxide (NOx) emission amount is greater than 1×10¹⁹ mole/cm³, the constant current stress characteristics may be degraded at the edge portion of the display apparatus DV, thereby adversely affecting the reliability and luminance of the display apparatus DV.

A thickness t2 of the first inorganic insulating layer 102 may range from 1000 Å to 2000 Å. When the thickness t2 of the first inorganic insulating layer 102 is less than 1000 Å, the first inorganic insulating layer 102 may not appropriately perform insulation between the first semiconductor layer Act and the first gate electrode G1, thereby changing the characteristics of the first semiconductor layer Act. When the thickness t2 of the first inorganic insulating layer 102 is greater than 2000 Å, cost efficiency may be reduced in a process of manufacturing the display apparatus DV. However, the disclosure is not limited thereto. The first inorganic insulating layer 102 may be deposited in a high-temperature process, which will be described below in more detail.

In an embodiment, a second inorganic insulating layer 103 may be directly located on at least a part of the buffer layer 101. The second inorganic insulating layer 103 may include the same material as the first inorganic insulating layer 102. The second inorganic insulating layer 103 may include an inorganic insulating material such as silicon oxide (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), or zinc oxide (ZnO).

An upper electrode CE2 of the capacitor Cst may be located on the second inorganic insulating layer 103. A lower electrode CE1 of a capacitor Cst may be integrally provided with the first gate electrode G1. However, the disclosure is not limited thereto. The lower electrode CE1 of the capacitor Cst may be provided separately from the first gate electrode G1. An upper electrode CE2 of the capacitor Cst may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may have a single or multi-layer structure including the above material.

A third inorganic insulating layer 104 may be located on the upper electrode CE2 of the capacitor Cst. The third inorganic insulating layer 104 may include an inorganic insulating material such as silicon oxide (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), or zinc oxide (ZnO).

A source electrode SE and a drain electrode DE may be formed on the third inorganic insulating layer 104. The source electrode SE and the drain electrode DE may be located on the same layer and may include the same material. Each of the source electrode SE and the drain electrode DE may include a conductive material including molybdenum (Mo), aluminum (Al), copper (Cu), or titanium (Ti), and may have a single or multi-layer structure including the above material. For example, each of the drain electrode DE and the source electrode SE may have a multi-layer structure including Ti/Al/Ti.

The source electrode SE may be electrically connected to the source region S of the first semiconductor layer Act, and the drain electrode DE may be electrically connected to the drain region D of the first semiconductor layer Act.

A first organic insulating layer 105 may be located on the source electrode SE and the drain electrode DE. The first organic insulating layer 105 may cover the source electrode SE and the drain electrode DE. The first organic insulating layer 105 may be continuously formed on the substrate 100. The first organic insulating layer 105 may include an organic insulating material such as a general-purpose polymer (e.g., polymethyl methacrylate (PMMA) or polystyrene (PS)), a polymer derivative having a phenol-based group, an acrylic polymer, an imide-based polymer, an aryl ether-based polymer, an amide-based polymer, a fluorinated polymer, a p-xylene-based polymer, a vinyl alcohol-based polymer, or a blend thereof.

A second connection electrode CM2 may be located on the first organic insulating layer 105. The second connection electrode CM2 may be electrically connected to the drain electrode DE or the source electrode SE through a contact hole defined in the first organic insulating layer 105. The second connection electrode CM2 may include a material having excellent conductivity. The second connection electrode CM2 may include a conductive material including molybdenum (Mo), aluminum (Al), copper (Cu), or titanium (Ti), and may have a single or multi-layer structure including the above material. For example, the second connection electrode CM2 may have a multi-layer structure including Ti/Al/Ti.

A second organic insulating layer 106 may be located on the second connection electrode CM2. The second organic insulating layer 106 may include an organic insulating material such as a general-purpose polymer such as polymethyl methacrylate (PMMA) or polystyrene (PS), a polymer derivative having a phenol-based group, an acrylic polymer, an imide-based polymer, an aryl ether-based polymer, an amide-based polymer, a fluorinated polymer, a p-xylene-based polymer, a vinyl alcohol-based polymer, or a blend thereof.

A first electrode of a light-emitting diode may be located on the second organic insulating layer 106. In this regard, FIGS. 5A and 5B illustrate a first electrode 150 of a first organic light-emitting diode OLED. In this case, the first electrode 150 may be an anode.

The first electrode 150 may be electrically connected to the second connection electrode CM2 through a contact hole defined in the second organic insulating layer 106. The first electrode 150 may be electrically connected to a pixel circuit including the first thin-film transistor TFT, through contact holes formed in the first organic insulating layer 105 and the second organic insulating layer 106.

The first electrode 150 may include a transparent conductive oxide such as indium tin oxide (ITO), indium zinc oxide (IZO), zinc oxide (ZnO), indium oxide (In₂O₃), indium gallium oxide (IGO), or aluminum zinc oxide (AZO). Alternatively, the first electrode 150 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. Alternatively, the first electrode 150 may further include a film formed of ITO, IZO, ZnO, or In₂O₃ over/under the reflective film. For example, the first electrode 150 may have a three-layer structure in which an ITO layer, a silver (Ag) layer, and an ITO layer are stacked.

A bank layer 107 may cover an edge of the first electrode 150, and may include a first bank opening B-OP1 above a central portion of the first electrode 150 (or through which at least a part of the first electrode 150 is exposed). The bank layer 107 may include an organic insulating material such as polyimide.

An intermediate layer 160 may contact the first electrode 150 through the first bank opening B-OP1 of the bank layer 107. A stacked structure of the first electrode 150, the intermediate layer 160, and a second electrode 170 located in the first bank opening B-OP1 may emit light of a certain color. The first bank opening B-OP1 of the bank layer 107 may correspond to an emission area EA that emits light. For example, a size (or width) of the first bank opening B-OP1 of the bank layer 107 may correspond to a size (or width) of the emission area EA.

Although not shown, the intermediate layer 160 may include an emission layer. The emission layer may include a high molecular weight organic material or a low molecular weight organic material emitting light of a certain color. As described with reference to FIG. 2, when the light-emitting diode layer 300 (see FIG. 2) emits blue light, the emission layer may include a high molecular weight organic material or a low molecular weight organic material emitting blue light.

In an embodiment, although not shown, the intermediate layer 160 may include at least one functional layer located over or under the emission layer. For example, as shown in FIGS. 5A and 5B, the intermediate layer 160 may include a first functional layer located under the emission layer and/or a second functional layer located over the emission layer. The first functional layer may be located between the first electrode 150 and the emission layer, and the second functional layer may be located between the emission layer and the second electrode 170 described below.

The first functional layer may include a hole transport layer (HTL) and/or a hole injection layer (HIL). The second functional layer may include an electron transport layer (ETL) and/or an electron injection layer (EIL).

The second electrode 170 may be located on the intermediate layer 160. The second electrode 170 may be, for example, a cathode. The second electrode 170 may be formed of a conductive material having a low work function. For example, the second electrode 170 may include a (semi-)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the second electrode 170 may further include a layer formed of ITO, IZO, ZnO, or In₂O₃ on the (semi-)transparent layer including the above material.

In an embodiment, the encapsulation layer 400 may be located on the second electrode 170. The encapsulation layer 400 may include at least one inorganic encapsulation layer and at least one organic encapsulation layer. In an embodiment, the encapsulation layer 400 may include a first inorganic encapsulation layer 410, an organic encapsulation layer 420, and a second inorganic encapsulation layer 430. The organic encapsulation layer 420 may be located between the first inorganic encapsulation layer 410 and the second inorganic encapsulation layer 430.

Each of the first and second inorganic encapsulation layers 410 and 430 may include at least one inorganic insulating material. The inorganic insulating material may include aluminum oxide, titanium oxide, tantalum oxide, hafnium oxide, zinc oxide, silicon oxide, silicon nitride, and/or silicon oxynitride.

The organic encapsulation layer 420 may include a polymer-based material. Examples of the polymer-based material may include an acrylic resin, an epoxy resin, polyimide, and polyethylene. For example, the organic encapsulation layer 420 may include an acrylic resin such as polymethyl methacrylate or polyacrylic acid. The organic encapsulation layer 420 may be formed by curing a monomer or applying a polymer.

An intermediate material layer 501 may be located on the encapsulation layer 400. The intermediate material layer 501 may include an inorganic insulating material and/or an organic insulating material. The color conversion-transmissive layer 500 may be located on the intermediate material layer 501. In this regard, FIGS. 5A and 5B illustrate a light blocking unit 540 of the color conversion-transmissive layer 500, and a first color conversion unit 510 located in an opening area defined by the light blocking unit 540.

A barrier layer 550 may be formed on the color conversion-transmissive layer 500. The barrier layer 550 may include an inorganic insulating material such as silicon oxide, silicon nitride, and/or silicon oxynitride.

The color layer 600 may be located on the color conversion-transmissive layer 500. In this regard, FIGS. 5A and 5B illustrate a light blocking unit 640 of the color layer 600 and a first color filter 610 located in an opening area defined by the light blocking unit 640. The light blocking unit 540 (hereinafter, referred to as a first light blocking unit) of the color conversion-transmissive layer 500 and the light blocking unit 640 (hereinafter, referred to as a second light blocking unit) of the color layer 600 may overlap each other.

Each of the first light blocking unit 540 and the second light blocking unit 640 may include a light blocking material. For example, each of the first light blocking unit 540 and the second light blocking unit 640 may include an organic material having a certain color such as black. For example, each of the first light blocking unit 540 and the second light blocking unit 640 may include a polyimide (PI)-based binder and a pigment in which red, green, and blue colors are mixed. Alternatively, each of the first light blocking unit 540 and the second light blocking unit 640 may include a cardo-based binder resin and a mixture of a lactam black pigment and a blue pigment. Alternatively, each of the first light blocking unit 540 and the second light blocking unit 640 may include carbon black.

In an embodiment, the first light blocking unit 540 and the second light blocking unit 640 may include the same material. Alternatively, the second light blocking unit 640 may have a structure in which at least two color filters for forming the color layer 600 overlap each other. For example, the second light blocking unit 640 may not include the above-described light blocking material, and may have a structure in which two or more color filter materials selected from among the first to third color filters 610, 620, and 630 (see FIG. 2) are stacked.

The light-transmitting base layer 700 may include glass or a light-transmitting organic material. The light-transmitting base layer 700 may include a light-transmitting organic material such as an acrylic resin.

Referring to FIG. 5B, in an embodiment, an interlayer insulating layer 111 and a second gate electrode G2 may be located between the buffer layer 101 and the first gate electrode G1. The interlayer insulating layer 111 is an inorganic insulating layer and may include an inorganic insulating material such as silicon oxide (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), or zinc oxide (ZnO).

When the first semiconductor layer Act includes an oxide semiconductor, the second gate electrode G2 may function as a lower gate electrode of the first thin-film transistor TFT.

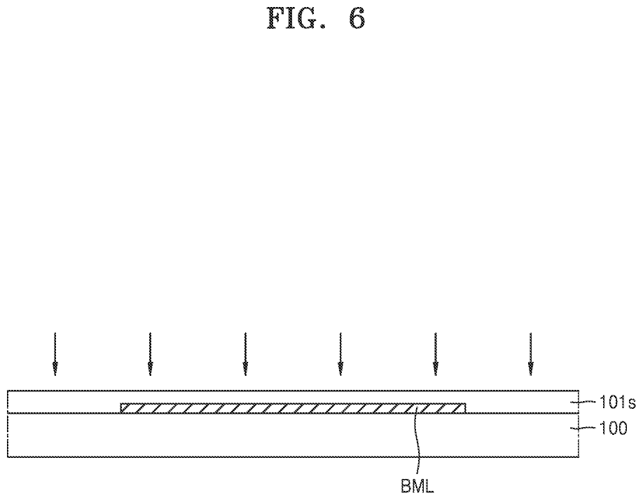

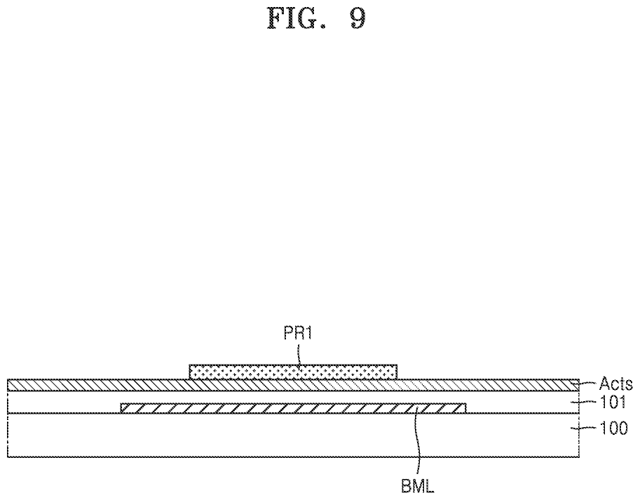

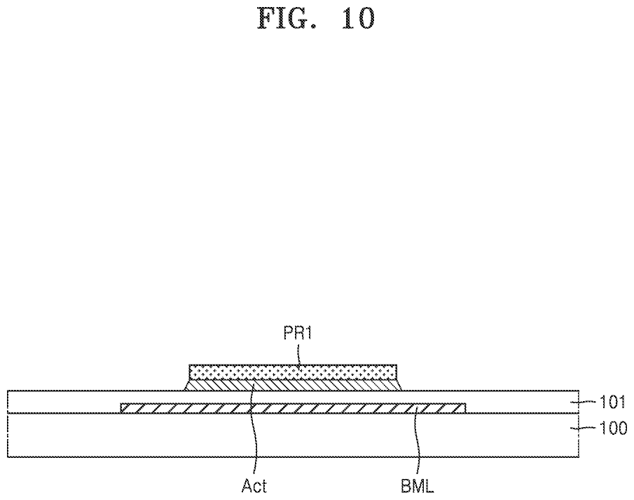

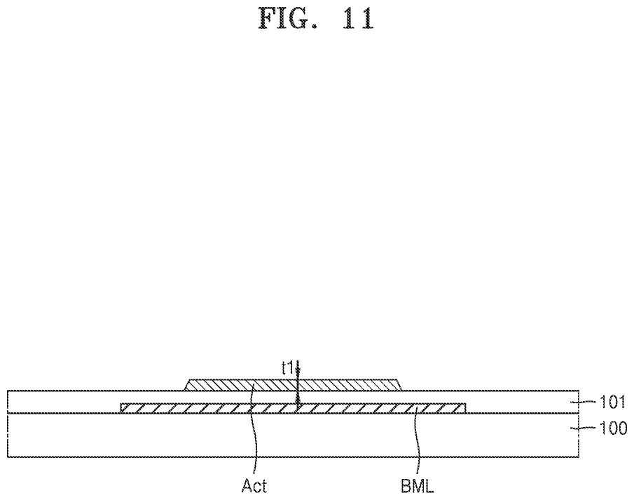

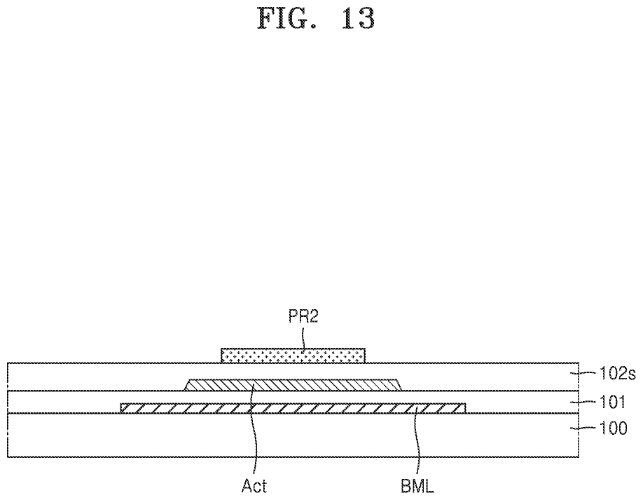

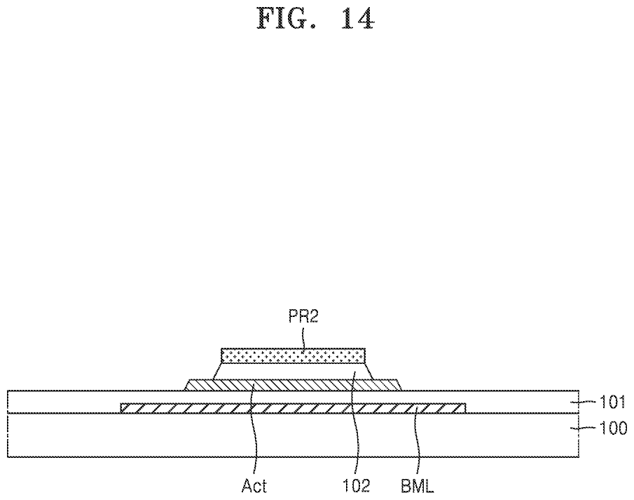

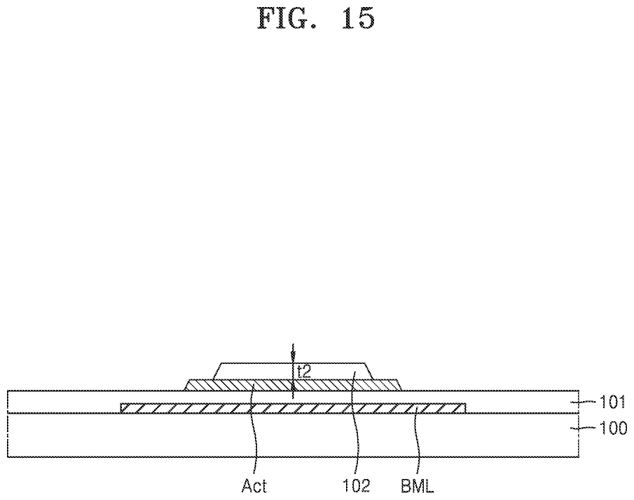

FIGS. 6 to 15 are cross-sectional views schematically illustrating a method of manufacturing a display apparatus.

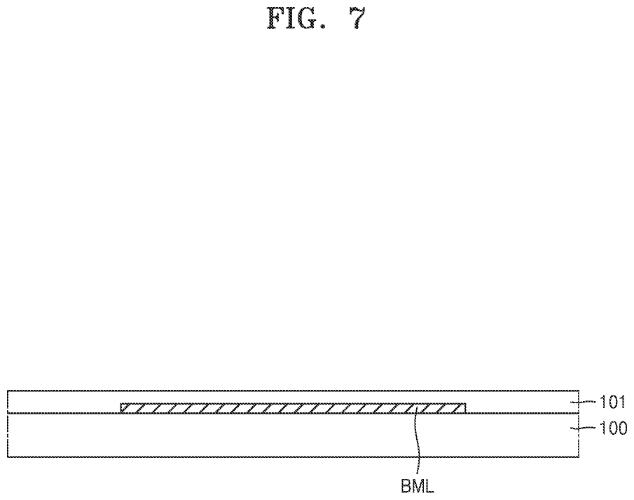

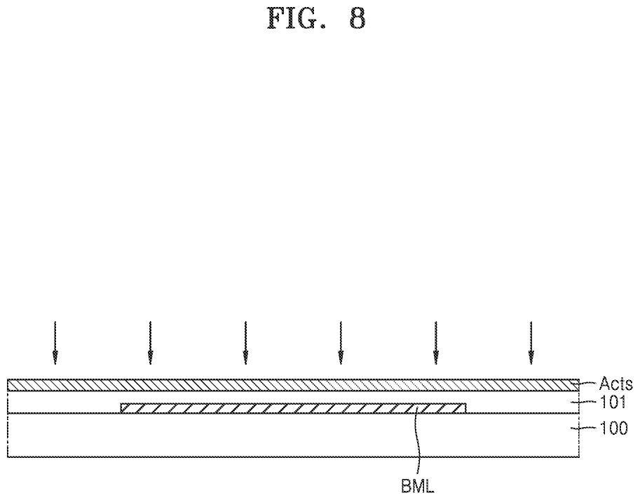

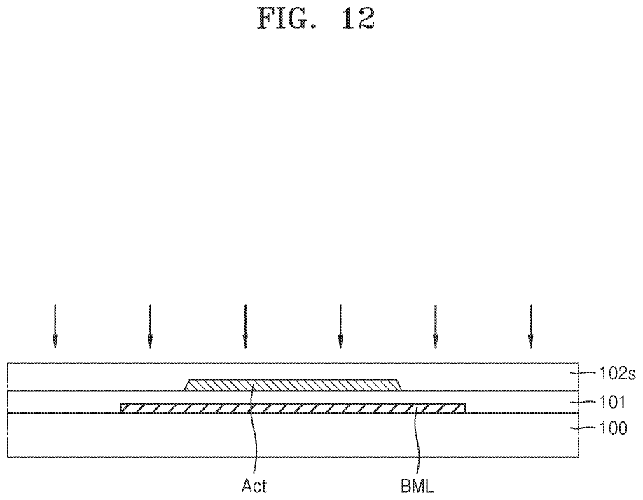

In detail, FIGS. 6 and 7 illustrate a process of forming the buffer layer 101 on the substrate 100. FIGS. 8 to 11 illustrate a process of forming the first semiconductor layer Act on the buffer layer 101. FIGS. 12 to 15 illustrate a process of forming the first inorganic insulating layer 102 on the first semiconductor layer Act.

Referring to FIGS. 6 and 7, a lower metal layer BML may be formed on the substrate 100. The lower metal layer BML may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu). The lower metal layer BML may have a single or multi-layer structure including the above material.

In an embodiment, the buffer layer 101 may be formed on the lower metal layer BML through a plasma-enhanced chemical vapor deposition (PECVD) process, and then the buffer layer 101 may become more robust through hydrogen (H₂) plasma treatment.

The buffer layer 101 may include an inorganic insulating material such as silicon nitride (SiNx), silicon oxynitride (SiON), or silicon oxide (SiO₂), and may have a single or multi-layer structure including the inorganic insulating material.

Dangling bonds including a buffer layer forming material 101s may be reduced by introducing hydrogen (H₂) gas in a process of forming the buffer layer 101, thereby improving the film density of the buffer layer.

When the film density of the buffer layer 101 is improved through the addition of hydrogen (H₂) plasma treatment, a degree of damage to an interface of the buffer layer 101 under the first semiconductor layer Act due to a sputtering process of forming the first semiconductor layer Act on the buffer layer 101 may be reduced. Compared to a case where the hydrogen (H₂) plasma treatment is not performed, a degree of damage to a top surface of the buffer layer 101 may be reduced, thereby increasing the amount of hydrogen (H₂) emitted from the buffer layer 101. In an embodiment, a hydrogen (H₂) emission amount of the buffer layer 101 formed through the hydrogen (H₂) plasma treatment may be at least 3×10¹⁹ mole/cm³. Also, an H₂ concentration in the film of the buffer layer 101 formed through the hydrogen (H₂) plasma treatment may be no higher than 8×10²⁰ atom/cm³.

Referring to FIGS. 8 to 11, a first semiconductor layer forming material Acts may be deposited on the buffer layer 101 through a sputtering process. The first semiconductor layer forming material Acts may include an oxide semiconductor. The first semiconductor layer forming material Acts may include at least one of indium gallium zinc oxide (IGZO), indium tin gallium oxide (ITGO), indium tin gallium zinc oxide (ITGZO), indium tin oxide (ITO), indium gallium oxide (IGO), or indium zinc oxide (IZO).

In a step of forming the first semiconductor layer forming material Acts through the sputtering process, damage to the buffer layer 101 located under the first semiconductor layer forming material Acts may be reduced. In the step of depositing the first semiconductor layer forming material Acts, damage to the buffer layer 101 may be reduced. When damage to an interface of a channel portion is reduced, the constant current stress characteristics of the display apparatus DV may be improved, thereby improving the reliability or luminance of the display apparatus DV.

In the step of depositing the first semiconductor layer forming material Acts through the sputtering process, in order to reduce damage to the buffer layer 101 located under the first semiconductor layer forming material Acts, power may range from 4 KW to 11 KW. When power is less than 4 KW in the step of locating the first semiconductor layer forming material Acts through the sputtering process, the characteristics of the first semiconductor layer forming material Acts may be changed. When power is greater than 11 KW in the step of locating the first semiconductor layer forming material Acts through the sputtering process, the buffer layer 101 may be damaged, the amount of hydrogen (H₂) emitted from the buffer layer 101 may be reduced, and thus, the constant current stress characteristics may be degraded at an edge portion of the display apparatus DV.

During the deposition of the first semiconductor layer forming material Acts through the sputtering process, pressure may range from 0.3 Pa to 0.5 Pa. When pressure is less than 0.3 Pa in the step of locating the first semiconductor layer forming material Acts through the sputtering process, the characteristics of the first semiconductor layer forming material Acts may be changed, and a desired threshold voltage or electron mobility of the first thin-film transistor TFT may not be derived. When pressure in the step of locating the first semiconductor layer forming material Acts through the sputtering process is greater than 0.5 Pa, the buffer layer 101 may be damaged, the amount of hydrogen (H₂) emitted from the buffer layer 101 may be reduced, and thus, the constant current stress characteristics may be degraded at the edge portion of the display apparatus DV, thereby adversely affecting the reliability or luminance of the display apparatus DV.

During the deposition of the first semiconductor layer forming material Acts through the sputtering process, partial pressure of oxygen (O₂) may range from 20% to 40%. When partial pressure of oxygen (O₂) in the step of locating the first semiconductor layer forming material Acts through the sputtering process is less than 20%, the characteristics of the first semiconductor layer forming material Acts may be changed, and a desired threshold voltage or electron mobility of the first thin-film transistor TFT may not be derived. When partial pressure of oxygen (O₂) is greater than 40% while locating the first semiconductor layer forming material Acts through the sputtering process, the buffer layer 101 may be damaged, the amount of hydrogen (H₂) emitted from the buffer layer 101 may be reduced, and thus, the constant current stress characteristics may be degraded at the edge portion of the display apparatus DV, thereby adversely affecting the reliability or luminance of the display apparatus DV.

During the deposition, the first semiconductor layer forming material Acts through the sputtering process, defects of the lower buffer layer due to plasma damage may be 8×10¹⁴ spins/cm² or less. When defects of the lower buffer layer due to plasma damage in the step of locating the first semiconductor layer forming material Acts through the sputtering process is greater than 8×10¹⁴ spins/cm², the buffer layer 101 may be damaged, the amount of hydrogen (H₂) emitted from the buffer layer 101 may be reduced, and thus, the constant current stress characteristics may be degraded at the edge portion of the display apparatus DV, thereby adversely affecting the reliability or luminance of the display apparatus DV.

In an embodiment, a first photoresist PR1 may be located on at least a part of the first semiconductor layer forming material Acts. The first semiconductor layer Act may be formed when at least a part of the first semiconductor layer forming material Acts is removed through an etching process from the area that is not covered by the first photoresist PR1. Next, the first photoresist PR1 may be removed.

The thickness t1 of the first semiconductor layer Act may range from 20 Å to 400 Å. When the thickness t1 of the first semiconductor layer Act is less than 20 Å or greater than 400 Å, the characteristics of the first semiconductor layer Act may be changed, and a desired threshold voltage or electron mobility of the first thin-film transistor TFT may not be derived.

Referring to FIGS. 12 to 15, a first inorganic insulating layer forming material 102s may be located on the first semiconductor layer Act. The first inorganic insulating layer forming material 102s may include an inorganic insulating material such as silicon oxide (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), or zinc oxide (ZnO).

In a process of depositing the first inorganic insulating layer forming material 102s on the first semiconductor layer Act, a temperature of the process may range from 300 C° C. to 400° C. When a temperature of the process of depositing the first inorganic insulating layer forming material 102s on the first semiconductor layer Act ranges from 300° C. to 400° C., the reactivity of a reaction for forming an inorganic insulating material such as silicon oxide (SiOx) by injecting a reactant (e.g., N₂O or SiH₄) may be increased, increasing hydrogen (H₂) outgassing from the first inorganic insulating layer forming material 102s or reducing the amount of nitrogen oxide (NOx) outgassing. When a temperature of the process of depositing the first inorganic insulating layer forming material 102s on the first semiconductor layer Act is lower than 300° C. or higher than 400° C., due to a difference in the reactivity of a reaction for forming the first inorganic insulating layer forming material 102s, hydrogen (H₂) or nitrogen oxide (NOx) outgassing and vacancy from the first inorganic insulating layer forming material 102s, H and O concentrations in the film, etc. may be changed, and thus, the characteristics of the display apparatus DV may be changed, thereby adversely affecting the reliability or luminance.

In an embodiment, a second photoresist PR2 may be located on at least a part of the first inorganic insulating layer forming material 102s. At least a part of the first inorganic insulating layer forming material 102s where the second photoresist PR2 is not located may be removed, to form the first inorganic insulating layer 102. Next, the second photoresist PR2 may be removed.

A hydrogen (H₂) emission amount of the first inorganic insulating layer 102 formed by depositing the first inorganic insulating layer forming material 102s through the high-temperature process may be 1×10¹⁹ mole/cm³ or more, which correlates with a nitrogen oxide (NOx) emission amount of the first inorganic insulating layer 102 being no higher than 1×10¹⁹ mole/cm³. Due to an increase in hydrogen (H₂) outgassing or a decrease in nitrogen oxide (NOx) outgassing of the first inorganic insulating layer 102 formed through the high-temperature process, the constant current stress characteristics at the edge portion of the display apparatus DV may be improved, thereby positively affecting the reliability or luminance of the display apparatus DV.

The thickness t2 of the first inorganic insulating layer 102 may range from 1000 Å to 2000 Å. When the thickness t2 of the first inorganic insulating layer 102 is less than 1000 Å, the first inorganic insulating layer 102 may not appropriately perform insulation between the first semiconductor layer Act and the first gate electrode G1, and thus, the characteristics of the first semiconductor layer Act may be changed. When the thickness t2 of the first inorganic insulating layer 102 is greater than 2000 Å, cost efficiency may be reduced in a process of manufacturing the display apparatus DV. However, the disclosure is not limited thereto.

In the related art, at an edge portion compared to a central portion of a substrate of a display apparatus, a degree of damage to an interface between the buffer layer 101 and the first semiconductor layer Act during a process of depositing a semiconductor layer on the buffer layer 101 may be high. At the edge portion of the substrate of the display apparatus, because the degree of damage to the interface between the buffer layer 101 and the semiconductor layer Act is increased compared to the central portion of the substrate 100, a portion including the damaged interface at the edge of the substrate 100 may act as an electron trap site. In the entire process of the display apparatus, at the edge portion compared to the central portion of the substrate 100 of the display apparatus, hydrogen (H₂) outgassing from an inorganic insulating layer or an organic insulating layer on the substrate 100 may be reduced or nitrogen oxide (NOx) outgassing may be increased. Due to a decrease in hydrogen (H₂) outgassing or an increase in nitrogen oxide (NOx) outgassing at the edge portion compared to the central portion of the substrate 100 of the display apparatus, the constant current stress characteristics may be degraded at the edge portion compared to the central portion of the substrate 100, thereby reducing the reliability or luminance of the display apparatus.

In an embodiment, however, a hydrogen (H₂) emission amount of the buffer layer 101 may be increased by improving the film density of the buffer layer 101 through hydrogen (H₂) plasma treatment. The degree of damage to the buffer layer 101 may be reduced and a hydrogen (H₂) emission amount of the buffer layer 101 may be increased by adjusting power, pressure, or partial pressure of oxygen in a step of forming the first semiconductor layer Act through a sputtering process. Also, hydrogen (H₂) outgassing from the first inorganic insulating layer 102 may be increased or nitrogen oxide (NOx) outgassing may be reduced by forming the first inorganic insulating layer 102 through high-temperature film deposition. A degree of damage to the buffer layer 101 may be reduced, and hydrogen (H₂) outgassing from the buffer layer 101 or the first inorganic insulating layer 102 may be increased or nitrogen oxide (NOx) outgassing may be reduced by changing a process condition, and the constant current stress characteristics at the edge portion of the display apparatus DV may be improved, thereby positively affecting the reliability or luminance of the display apparatus DV.

According to an embodiment as described above, a display apparatus with improved reliability and visibility and a method of manufacturing the display apparatus may be provided. However, the scope of the disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims.

What is claimed is:

1. A display apparatus comprising:
a substrate;
a buffer layer located on the substrate;
a first thin-film transistor located on the buffer layer, the first thin-film transistor comprising a first semiconductor layer and a first gate electrode insulated from the first semiconductor layer, the first semiconductor layer comprising an oxide semiconductor; and
a first inorganic insulating layer located between the first semiconductor layer and the first gate electrode,
wherein a hydrogen (H₂) emission amount of the first inorganic insulating layer is at least 1×10¹⁹ mole/cm³.

2. The display apparatus of claim 1, wherein a nitrogen oxide (NOx) emission amount of the first inorganic insulating layer is no higher than 1×10¹⁹ mole/cm³.

3. The display apparatus of claim 1, wherein a thickness of the first inorganic insulating layer ranges from about 1000 Å to about 2000 Å.

4. The display apparatus of claim 1, wherein the first inorganic insulating layer comprises silicon oxide (SiOx).

5. The display apparatus of claim 1, wherein a hydrogen (H₂) emission amount of the buffer layer is at least 3×10¹⁹ mole/cm³.

6. The display apparatus of claim 1, wherein a hydrogen (H₂) concentration in the buffer layer is no higher than 8×10²⁰ atom/cm³.

7. The display apparatus of claim 1, wherein the buffer layer comprises one of silicon oxide (SiOx) and silicon nitride (SiNx).

8. The display apparatus of claim 1, wherein a thickness of the first semiconductor layer ranges from about 20 Å to about 400 Å.

9. The display apparatus of claim 1, wherein the first semiconductor layer comprises at least one of indium gallium zinc oxide (IGZO), indium tin gallium oxide (ITGO), indium tin gallium zinc oxide (ITGZO), indium tin oxide (ITO), indium gallium oxide (IGO), and indium zinc oxide (IZO).

10. A method of manufacturing a display apparatus, the method comprising:
forming a buffer layer on a substrate;
forming, on the buffer layer, a first semiconductor layer comprising an oxide semiconductor;
forming a first inorganic insulating layer on the first semiconductor layer; and
forming a first gate electrode on the first inorganic insulating layer to form a first thin-film transistor comprising the first semiconductor layer and the first gate electrode insulated from the first semiconductor layer,
wherein a hydrogen (H₂) emission amount of the first inorganic insulating layer is at least 1×10¹⁹ mole/cm³.

11. The method of claim 10, wherein the forming of the buffer layer on the substrate comprises forming the buffer layer on the substrate through hydrogen (H₂) plasma treatment.

12. The method of claim 10, wherein the forming of the first semiconductor layer comprising the oxide semiconductor comprises performing a sputtering process,
wherein power in the sputtering process ranges from about 4 KW to about 11 kW.

13. The method of claim 10, wherein the forming of the first semiconductor layer comprising the oxide semiconductor comprises performing a sputtering process,
wherein pressure in the sputtering process ranges from about 0.3 Pa to about 0.5 Pa.

14. The method of claim 10, wherein the forming of the first semiconductor layer comprising the oxide semiconductor comprises performing a sputtering process,
wherein partial pressure of oxygen (O₂) in the sputtering process ranges from about 20% to about 40%.

15. The method of claim 10, wherein the forming of the first semiconductor layer comprising the oxide semiconductor comprises performing a sputtering process,
wherein defects of a lower buffer layer due to plasma damage in the sputtering process are no higher than 8×10¹⁴ spins/cm².

16. The method of claim 10, wherein, in the forming of the first inorganic insulating layer on the first semiconductor layer, a temperature of a process ranges from about 300° C. to about 400° C.

17. The method of claim 10, wherein a nitrogen oxide (NOx) emission amount of the first inorganic insulating layer is no higher than 1×10¹⁹ mole/cm³.

18. The method of claim 10, wherein a hydrogen (H₂) emission amount of the first inorganic insulating layer is at least 1×10¹⁹ mole/cm³.

19. The method of claim 10, wherein a thickness of the first inorganic insulating layer ranges from about 1000 Å to about 2000 Å.

20. The method of claim 10, wherein a thickness of the first semiconductor layer ranges from about 20 Å to about 400 Å.
